(19) United States
(12) Patent Application Publication
(10) Pub. No.: US 2005/0101133 A1
(43) Pub. Date: May 12, 2005

(54) Method for making negative thermal expansion material zirconium tungstate

(76) Inventors: Der Liang Tzeng, Sinjhuang City (TW); Hou Cheng Chang, Jhonghe City (TW); Jen Chin Wu, Jhongli City (TW)

Correspondence Address: STEVENS, DAVIS, MILLER & MOSHER, L.L.P.;Suite 850, 1615 L. Street, N.W., Washington, DC, 20036, US

(21) Appl. No.: 10/703,563

(22) Filed: Nov. 10, 2003

(51) Int. Cl. H01L 21/302; H01L 21/461

(52) U.S. Cl. 438/689

(57) ABSTRACT

A method for making negative thermal expansion material zirconium tungstate (ZrW₂O₈) comprise: (a)forming a gel wrapped solid product comprising a water-soluble zirconium compound, preferably zirconium oxyhalides or zirconium oxynitrates and a water-insoluble tungsten compound, preferably tungsten powder or tungsten oxide powder; and (b)heating the gel wrapped solid product to a temperature sufficient to form ZrW₂O₈; the temperature required for forming zirconium tungstate should be at least about 1165° C.; the upper limit of the temperature should be about 1250° C., and preferably should be about 1180˜1200° C.; and the time needed for the formation of zirconium tungstate is less than about 5 hours; this method has the advantages on enhancing the selectivity of the reactants, simplifying production process, reducing the cost of reagent, and facilitating the mass production for making ZrW₂O₈.

### BACKGROUND OF THE PRESENT INVENTION

1. Field of the Present Invention

The present invention relates to a method for making negative thermal expansion material zirconium tungstate (ZrW₂O₈).

2. Description of Prior Art

Most materials in general will expand upon heating, however there are some compounds such as zirconium tungstate (ZrW₂O₈) which exhibit isotropic negative thermal expansion upon heating from 0.3 to 1050 K, Sleight et al. “Negative Thermal Expansion from 0.3 to 1050 Kelvin in ZrW₂O₈” Science, 272,90-92(1996). This kind of specific property permits potential application in the fields of photo-electric communication, semiconductor, and dental material, etc.

Zirconium tungstate is a commonly known compound for a long time; its negative thermal expansion property was intensively discussed in the paper “Linear Thermal Expansion of Three Tungstates” published by Martinek et al. on J. Am. Ceram. Soc., 51,227-228(1968). However, owing to the difficulties in controlling their chemical process, no significant achievements have been reported during the past years.

Most researchers selected zirconium oxide (ZrO₂) and tungsten oxide (WO₃) as the starting reagents, which were ground and mixed together to form fine powder at first, and then heated at 1200° C. for a period of time, then the mixture was cooled rapidly to prevent from decomposing back to zirconium oxide and tungsten oxide.

For example, in 1959 Graham et al. originally published a paper “A New Ternary Oxide, ZrW₂O₈” on J. Am. Ceram. Soc., 42,570(1959), disclosed for producing ZrW₂O₈ by heating the mixture of zirconium oxide and tungsten oxide to a temperature of about 1200° C. for a period of 15 minutes. But the product obtained by this way contained a considerable amount of un-reacted zirconium oxide and tungsten oxide, mainly due to the volatility of tungsten oxide under high temperature and the poor reactivity of zirconium oxide.

The method described in the paper “Linear Thermal Expansion of Three Tungstates” by Martinek et al. in J. Am. Ceram. Soc., 51,227-228(1968), which disclosed for heating a mixture of zirconium oxide and tungstic acid (H₂WO₄) to a temperature of about 1150° C. for a period of 4 hours, and then cooling the mixture rapidly to obtain the tungstate compound, nonetheless the purity of zirconium tungstate was not reported in the paper.

A method for making ZrW₂O₈ was also reported in the paper by Chang et al. on J. Am. Ceram. Soc., 50,211-215(1967) entitled “Condensed Phase Relations in the Systems ZrO₂—WO₂—WO₃ and HfO₂—WO₂—WO₃”. The volatility of tungsten oxide at elevated temperature had been observed when the reactants were heated in sealed platinum tube to study the phase change of ZrO₂-WO₂—WO₃. The phase equilibrium study showed that the single phase ZrW₂O₈ could only be obtained from the sealed mixture of zirconium oxide and tungsten oxide in the proper stoichiometric ratio through prolonged heating at 1200° C. at least 24 hours. In 1970, Martinek pointed out in his paper “Subsolidus Equilibria in the System ZrO₂—WO₃—P₂O₅” published on J. Am. Ceram. Soc., 53,159-161, that ZrW₂O₈ cannot be formed below 1105° C., and consequently it needs to heat the reagents to 1200° C. for a period of at least 48 hours to obtain high purity zirconium tungstate.

In 1998, Ernst et al. published a paper on “Phonon Density of States and Negative Thermal Expansion in ZrW₂O₈” Nature, 396,147-149, which depicted a method for making ZrW₂O₈. They reported that the reagents of zirconium oxide and tungsten oxide were mixed according to the required proportion, ground and tableted before heated to 1180° C. for 5 hours under sufficient oxygen supply, and then the reaction mixture was cooled rapidly to obtain single crystals ZrW₂O₈.

In 1996 Sleight et al. disclosed a method for making ZrW₂O₈ in U.S. Pat. No. 5,514,360 “Negative Thermal Expansion Material” which chose zirconium oxyhalides or oxynitrates and tungstic acid (H₂WO₄) as starting reagents or else zirconium chloride (ZrCl₄) and tungsten chloride (WCl₆) as starting reagents. The starting reagents were dissolved in an appropriate solvent, well blended, and heated to 1200° C. for a period of 2-4 hours, and then cooled rapidly to room temperature to form the target product.

In 1999 Kong, Xiangyang et al. published paper on “Microwave Synthesis and Characterization of ZrW₂O₈ with Negative Thermal Expansion” J Chinese. Ceram. Soc., Vol.27 No.3, in which zirconium oxychloride and tungstic acid were employed as starting reagents, which were dissolved in an appropriate solvent, well mixed, filtered and heated to remove the solvent. Then the remaining solid was heated by microwave to a temperature within 800˜1000° C. for 30 minutes. The solid was rapidly cooled to room temperature. The high purity ZrW₂O₈ was obtained.

According to the above-mentioned methods for synthesizing ZrW₂O₈ could be classified into two major categories. One uses zirconium oxide and tungsten oxide as reactants which are heated to about 1200° C. over 5 hours. The drawback of this category involved complicated working process, e.g. tedious grinding and tableting. Second used zirconium oxyhalides and tungstic acid as reactants, or zirconium chloride and tungsten chloride as reactants which are heated to a temperature of 1200° C. for a period shortened to 2-4 hours, or heated by microwave to a temperature range of 800˜1000° C. for 30 minutes to obtain zirconium tungstate. The major drawback of this category was high material cost. In order to improve the shortcoming of the afore-mentioned methods, the method disclosed in the present invention has signified with a simpler chemical process, and lower material cost.

### SUMMARY OF THE PRESENT INVENTION

The purpose of present invention is to provide a new method for making ZrW₂O₈ which can simplify production process with lower cost of reagent, and facilitate mass production process.

In order to achieve the above-mentioned purpose, the method disclosed in the invention for making ZrW₂O₈ comprises the following steps: dissolving the zirconium compound in water to form aqueous solution; adding tungsten compound into the solution and followed by aqueous ammonia to form gel-wrapped mixture; removing water from the gel-wrapped mixture to form gel wrapped solid product; heating the gel wrapped solid product to a temperature within the primary temperature range to oxidize the tungsten powder; heating the gel wrapped solid product to a temperature within the secondary temperature range to form ZrW₂O₈. In this method the zirconium compounds are water-soluble zirconium oxyhalides or zirconium oxynitrates, the tungsten compounds are tungsten powder or tungsten oxide powder.

### BRIEF DESCRIPTION OF THE DRAWING FIGURES

FIG. 1 is an x-ray diffraction pattern showing substantially single phase ZrW₂O₈.

FIG. 2 is a curve illustrating the relative thermal expansion of ZrW₂O₈ over temperature.

### DETAILED DESCRITION OF THE PREFERRED EMBODIMENTS

Some of the zirconium compounds can be dissolved in water, such as zirconium oxyhalides, zirconium oxynitrates; and generally are purchased as hydrates. In the present invention, all these zirconium compounds may be used as the raw materials. However, in general, priority is given to those of lower cost and better availability such as the water-soluble compound zirconium oxyhalides including zirconium oxycholoride, zirconium oxybromide (ZrOBr₂) and zirconium oxyiodide (ZrOI₂).

For the tungsten compounds, tungsten powder and tungsten oxide power have the advantages of various particle size products, lower cost and better availability, are chosen as reactants. The particle size of tungsten compound is not strict restriction, but the particle size smaller than 20 μm is preferred.

Logically, the method for making zirconium tungstate as disclosed in the present invention, comprises two kinds of components in the reactants: The first component is water-soluble zirconium compound, preferably zirconium oxyhalides or zirconium oxynitrates. The second component is water-insoluble tungsten compound, preferably tungsten powder or tungsten oxide powder. And the preferred molar ratio between zirconium and tungsten is about 1:2. The way to form the gel-wrapped mixture is to dissolve the water-soluble first compound in water with stirring, and then add the water-insoluble second compound into the solution followed by adding aqueous ammonia or other alkali liquid into the solution to make the mixture into gel state wherein such a state that the second compound is gel-wrapped by the first compound, and then the gel-wrapped mixture is dehydrated and dried in the temperature range from 90° C. to 200° C., through heating process to form gel wrapped solid product.

The gel wrapped solid product is kept in a oxygen atmosphere and heat to oxidize the tungsten powder within the primary temperature range from 600° C. to 800° C. for 30 minutes. And then, raise the temperature to the secondary zirconium tungstate formation temperature, and hold for a required period of time to form zirconium tungstate, then cool rapidly to room temperature. The temperature required for forming zirconium tungstate should be at least 1165° C. The upper limit of the temperature should be 1250° C., and preferably should be 1180˜1200° C. The time needed for the formation of zirconium tungstate is less than about 5 hours, depending on the purity of zirconium tungstate and the amount of reactant used for the reaction. In case there is any inhomogeneous observed phases due to over large amount of product formed, the product can be ground and heat again with the preferred temperature being about 1180˜1200° C. The required reaction time for this step is also less than about 5 hours. This method is very useful for mass production of ZrW₂O₈.

In the following two examples of the preferred embodiment of the invention are employed to describe the process of the new method and the compounds formed in the process.

### EXAMPLE 1

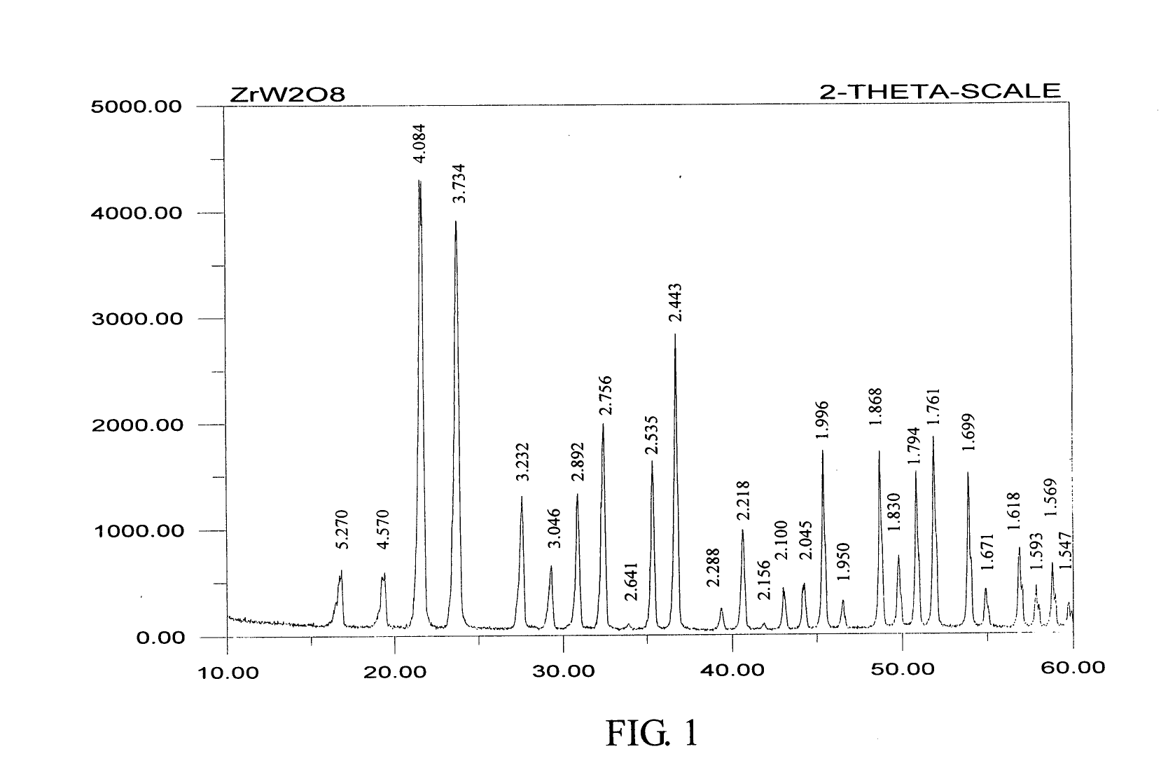

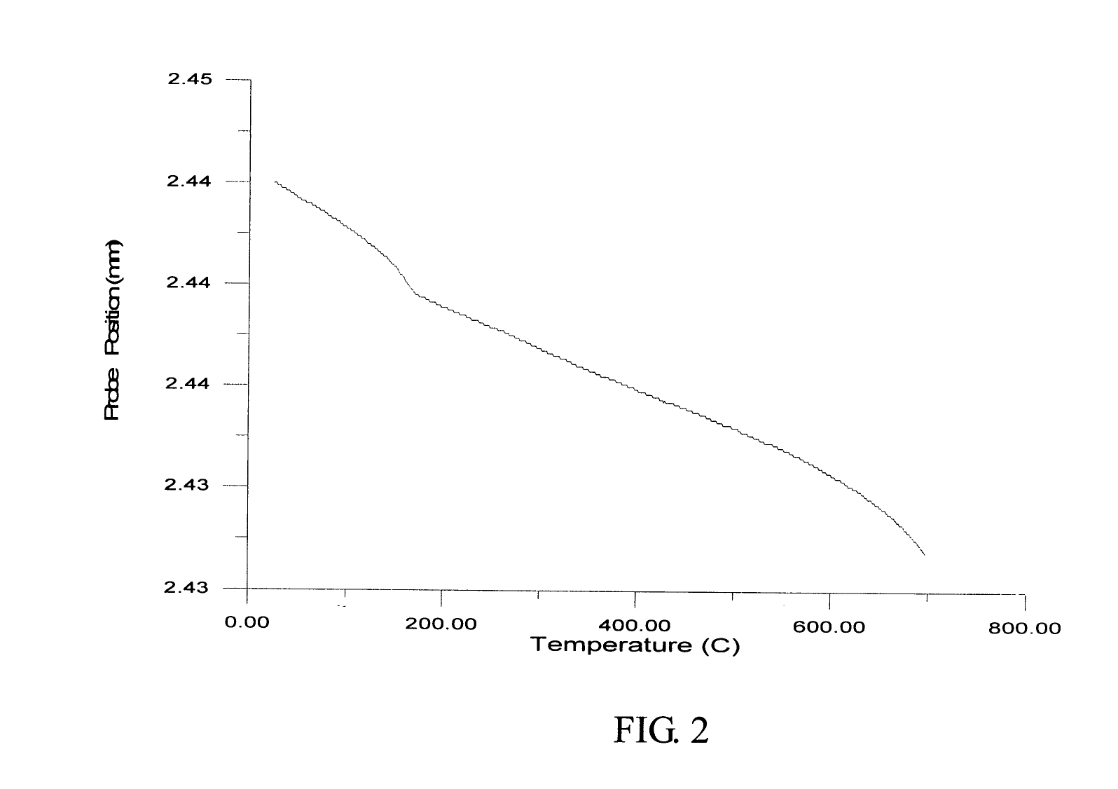

3.223 gram of ZrOCl₂·8H₂O were dissolved in about 30 ml of water, then 3.678 grams tungsten powder was added into the solution with stirring. Aqueous ammonia was added slowly until the solution was in gel state and continued stirring for 10 minutes. The gel wrapped solution was filtered and washed by diluted aqueous ammonia 3 times, thereby producing a gel wrapped product. The gel product was dried at 140° C. for 3 hours, then heated at 700° C. for 0.5 hours, and then heated at 1200° C. for 4 hours, followed by rapid cooling to room temperature. The product was found by x-ray diffraction (FIG. 1) to be single phase ZrW₂O₈, and the relative thermal expansion of ZrW₂O₈ over temperature was shown in FIG. 2.

### EXAMPLE 2

3.223 grams of ZrOCl₂·8H₂O, were dissolved in about 30 ml of water, and then added 4.637 grams of WO₃ into the solution with stirring. Aqueous ammonia was added slowly until the solution was in gel state and continued stirring for 10 minutes. The gel wrapped solution was filtered and washed by diluted aqueous ammonia 3 times, thereby producing a gel wrapped product. The gel wrapped product was dried at 130° C. for 3 hours, then heated at 1190° C. for 4.5 hours, followed by rapid cooling to room temperature. X-ray diffraction showed single phase ZrW₂O₈.

The purpose of the afore-mentioned examples provided is only for the convenience of making illustration of the features of the method disclosed by the present invention. These examples should not be construed to limit the present invention to those particular features as described above. Therefore the scope of patent right of the present invention shall be solely determined by the claims appended hereto.

1. A method for making zirconium tungstate comprising:
(a) forming a gel-wrapped mixture comprising a first compound including water-soluble zirconium compound, and a second compound including water-insoluble tungsten compound;
(b) dehydrating the gel-wrapped mixture to form gel wrapped solid product; and
(c) heating the gel wrapped solid product at a temperature within the primary temperature range to oxidize the tungsten powder followed by heating the solid again at a temperature within the secondary temperature range to form zirconium tungstate.

2. The method according to claim 1, wherein in step (a) the second compound is added to the first compound's aqueous solution with stirring; and adding aqueous ammonia or other alkali liquid slowly into above solution to make it into gel state with stirring, wherein such a state that the second compound is gel-wrapped by the first compound.

3. The method according to claim 1, wherein the gel-wrapped mixture in step (a) has a relative molar ratio of Zirconium to Tungsten about 1:2.

4. The method according to claim 1, wherein the temperature range of the primary temperature as described in step (b), in case the gel wrapped solid product contains tungsten powder, the temperature is within the range from 600° C. to 800° C.

5. The method according to claim 4, wherein the time heating the gel wrapped solid product is about 30 minutes.

6. The method according to claim 1, wherein the temperature range of the secondary temperature as described in step (b) is within the range from 1165° C. to 1250° C. for forming high purity zirconium tungstate.

7. The method according to claim 6, wherein the time period needed for forming zirconium tungstate is under 5 hours, and followed by rapid cooling to room temperature.

8. The method according to claim 1, wherein the first compound is selected from the group consisting of ZrOCl₂, ZrOBr₂, ZrOI₂ and ZrO(NO₃)₂.

9. The method according to claim 1, wherein the second compound is selected from the group consisting of tungsten powder and tungsten oxide powder.

10. The method according to claim 9, wherein the particle size of the tungsten powder is smaller than 20 μm.

11. A method for making zirconium tungstate comprising:
(a) forming a gel-wrapped mixture comprising a first compound including water-soluble zirconium compound, and a second compound including water-insoluble tungsten compound;
(b) dehydrating the gel-wrapped mixture to form gel wrapped solid product;
(c) heating the gel wrapped solid product at a temperature within the primary temperature range to oxidize the tungsten powder followed by heating the solid again at a temperature within the secondary temperature range to form zirconium tungstate; and
(d) further grinding the product of zirconium tungstate, and having the ground product well blended and calcined at a temperature within the range from 1165° C. to 1250° C. for a reaction time period under 5 hours to facilitate the mass production of zirconium tungstate.
